(19) United States
(12) Patent Application Publication
(10) Pub. No.: US 2016/0284909 A1
(43) Pub. Date: Sep. 29, 2016

(54) MULTI-DIODE SOLAR CELLS

(71) Applicants: Gabriel Harley, Mountain View, CA (US); Seung Bum Rim, Palo Alto, CA (US); Keith Johnston, Palo Alto, CA (US); Matthieu Minault Reich, San Jose, CA (US)

(72) Inventors: Gabriel Harley, Mountain View, CA (US); Seung Bum Rim, Palo Alto, CA (US); Keith Johnston, Palo Alto, CA (US); Matthieu Minault Reich, San Jose, CA (US)

(21) Appl. No.: 14/672,044

(22) Filed: Mar. 27, 2015

(51) Int. Cl. H01L 31/05; H01L 31/0475; H01L 31/054

(52) U.S. Cl. CPC H01L 31/0508; H01L 31/0543; H01L 31/0475

(57) ABSTRACT

Solar cells can include a plurality of sub-cells that include a singulated and physically separated semiconductor portion such that adjacent ones of the singulated and physically separated semiconductor portions can have a groove therebetween. The solar cells can include a metallization structure that couples ones of the plurality of sub-cells. An interconnect structure can couple adjacent ones of the solar cells.

### BACKGROUND

Photovoltaic cells, commonly known as solar cells, are devices for direct conversion of solar radiation into electrical energy. Generally, solar cells are fabricated on a semiconductor wafer or substrate using semiconductor processing techniques to form a p-n junction near a surface of the substrate. Solar radiation impinging on the surface of, and entering into, the substrate creates electron and hole pairs in the bulk of the substrate. The electron and hole pairs migrate to p-doped and n-doped regions in the substrate, thereby generating a voltage differential between the doped regions. The doped regions are connected to conductive regions on the solar cell to direct an electrical current from the cell to an external circuit coupled thereto.

### BRIEF DESCRIPTION OF THE DRAWINGS

FIG. 1 illustrates a cross-sectional view of a solar cell prior to singulation to form physically separated sub-cells, in accordance with an embodiment of the present disclosure.

FIG. 2 illustrates a cross-sectional view of a solar cell subsequent to singulation to form physically separated sub-cells, in accordance with an embodiment of the present disclosure.

FIG. 3 illustrates a plan view from the metallization side of a solar cell that has been diced into two half wafers, each including a plurality of sub-cells, in accordance with an embodiment of the present disclosure.

FIG. 4 illustrates a plan view of the two half wafers of FIG. 3 coupled together in series, in accordance with an embodiment of the present disclosure.

FIG. 5 illustrates a plan view from the metallization side of another solar cell that has been diced into two half wafers, each including a plurality of sub-cells, in accordance with an embodiment of the present disclosure.

FIG. 6 illustrates a plan view of the two half wafers of FIG. 5 coupled together in series, in accordance with an embodiment of the present disclosure.

FIGS. 7-11 illustrate examples of two half wafers coupled together, according to some embodiments.

FIG. 12 illustrates an example graph of series resistance versus cell size, according to some embodiments.

FIGS. 13 and 14 illustrate example additional metallization structures that can be used in combination with the metallization structure of the disclosed multi-diode cells.

FIG. 15 illustrates three possible pathways for laser scribing for singulation of a solar cell to form sub-cells, in accordance with an embodiment of the present disclosure.

FIG. 16 is a flowchart representing operations in a method of fabricating a concentrating photovoltaic receiver, according to some embodiments.

### DETAILED DESCRIPTION

The following detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

This specification includes references to “one embodiment” or “an embodiment.” The appearances of the phrases “in one embodiment” or “in an embodiment” do not necessarily refer to the same embodiment. Particular features, structures, or characteristics may be combined in any suitable manner consistent with this disclosure.

Terminology. The following paragraphs provide definitions and/or context for terms found in this disclosure (including the appended claims):

“Comprising.” This term is open-ended. As used in the appended claims, this term does not foreclose additional structure or steps.

“Configured To.” Various units or components may be described or claimed as “configured to” perform a task or tasks. In such contexts, “configured to” is used to connote structure by indicating that the units/components include structure that performs those task or tasks during operation. As such, the unit/component can be said to be configured to perform the task even when the specified unit/component is not currently operational (e.g., is not on/active). Reciting that a unit/circuit/component is “configured to” perform one or more tasks is expressly intended not to invoke 35 U.S.C. §112, sixth paragraph, for that unit/component.

“First,” “Second,” etc. As used herein, these terms are used as labels for nouns that they precede, and do not imply any type of ordering (e.g., spatial, temporal, logical, etc.). For example, reference to a “first” sub-cell does not necessarily imply that this sub-cell is the first sub-cell in a sequence; instead the term “first” is used to differentiate this sub-cell from another sub-cell (e.g., a “second” sub-cell).

“Coupled”—The following description refers to elements or nodes or features being “coupled” together. As used herein, unless expressly stated otherwise, “coupled” means that one element/node/feature is directly or indirectly joined to (or directly or indirectly communicates with) another element/node/feature, and not necessarily mechanically.

“Inhibit”—As used herein, inhibit is used to describe a reducing or minimizing effect. When a component or feature is described as inhibiting an action, motion, or condition it may completely prevent the result or outcome or future state completely. Additionally, “inhibit” can also refer to a reduction or lessening of the outcome, performance, and/or effect which might otherwise occur. Accordingly, when a component, element, or feature is referred to as inhibiting a result or state, it need not completely prevent or eliminate the result or state.

In addition, certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, “side”, “outboard”, and “inboard” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

Solar cells having a plurality of sub-cells coupled by metallization structures, and singulation approaches to forming solar cells having a plurality of sub-cells coupled by metallization structures, are described herein. In the following description, numerous specific details are set forth, such as specific process flow operations, in order to provide a thorough understanding of embodiments of the present disclosure. It will be apparent to one skilled in the art that embodiments of the present disclosure may be practiced without these specific details. In other instances, well-known fabrication techniques, such as solar cell emitter region fabrication techniques, are not described in detail in order to not unnecessarily obscure embodiments of the present disclosure. Furthermore, it is to be understood that the various embodiments shown in the figures are illustrative representations and are not necessarily drawn to scale.

The specification first describes an example multi-diode solar cell structure, followed by specific examples of multi-diode solar cells for concentrating photovoltaic (PV) receivers. The specification also describes an example method for forming the disclosed structures. Various examples are provided throughout.

To give context for a solar cell having a plurality of sub-cells, a single solar cell (e.g., 125 mm, 156 mm, 210 mm) can be subdivided into smaller cells to allow for flexibility in module current and voltage, as well as flexibility in the metallization (e.g., thickness can be reduced with reduced current). As an example, a single silicon P/N diode has an open circuit voltage (Voc) of 0.6 to 0.74 V. A maximum power voltage (Vmp) may be approximately 0.63V for a solar cell. Thus, single diode cells will have a voltage of 0.63V. If 10 sub-diodes are produced on a single full-area wafer, and connected in series, the voltage would be 6.3V for the entire cell (at roughly 1/10^{th} the current, or about 0.5 A for a standard cell).

Having the ability to control the voltage conversely allows control over the current, which ultimately dictates the thickness of the metal required for a finished device, since power loss is associated with resistive losses in the metal. For example, for an interdigitated back contact (IBC) cell on a 5 inch wafer, the nominal finger length is 125 mm long, and requires approximately 30 microns of plated copper (Cu) to prevent grid losses. Moving to a 6 inch wafer extends the finger length to 156 millimeters, and since resistive losses go by the length squared, this may require a metal thickness of approximately 48 microns. The potential adds substantial cost to metallization, e.g., by having more direct material costs and by reducing the throughput of the tools. Thus, the ability to control the finger length and cell parametrics by moving to multiple diode solutions can allow for greater flexibility in the processing of solar cell metallization. In particular, for applications on larger cells, increasing the size of the cell also produces more current. Moreover, for a concentrating PV application, thicker metal is typically used to accommodate the higher current that is produced. By implementing a multi-diode approach for a concentrating PV, a lower current can be achieved thereby allowing thinner metal to be used, which can result in reduced cost and increased throughput.

Additionally, temperature of the devices in operation in the field is dependent on the current and generally should be minimized to avoid accelerated aging affects, and risks of higher temperatures should cells enter reverse bias. Furthermore, in general, lower current will improve the overall reliability of the PV receiver.

As described in greater detail below in association with the Figures, specific embodiments described herein can be implemented based on the understanding that metal or metallization structures having a thickness of greater than approximately 20 microns can be used to prevent power loss otherwise associated with silicon (Si)-cracking in a solar cell by using the metal to hold the cell together. Embodiments described herein provide a metal structure (e.g., by plating, or foil, or ribbon, etc.) that is bonded to a full-area wafer having sub-cells. In the multi-sub-cell approach, the metal can be patterned such that the sub-cell interconnects are formed in the same operation as the sub-cell metallization and are part of the metallization structure of the full solar cell having the multiple sub-cells. And in embodiments in which a half wafer form factor is used, the silicon and metal can be scribed and diced, respectively, to separate the full wafer into two separate half wafers, each with multiple sub-cells.

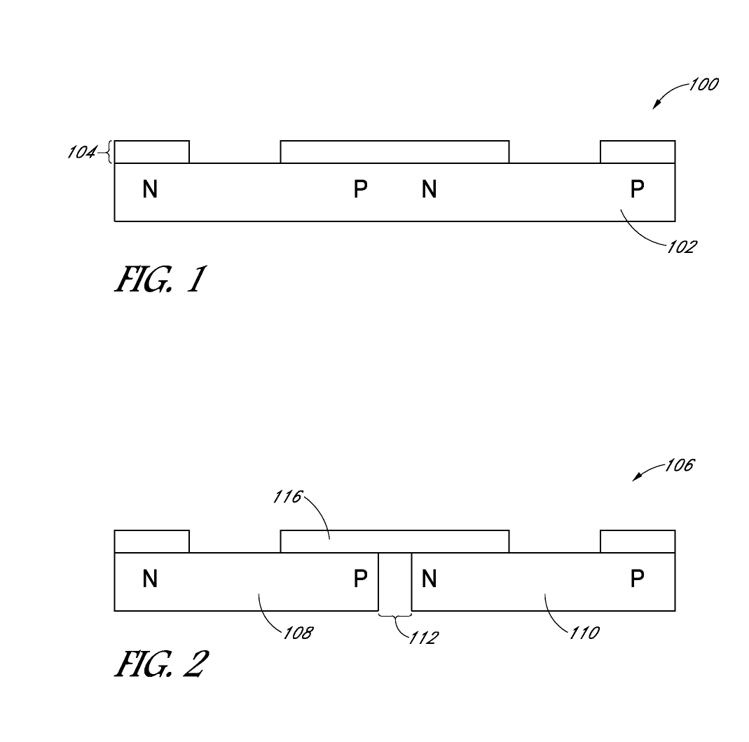

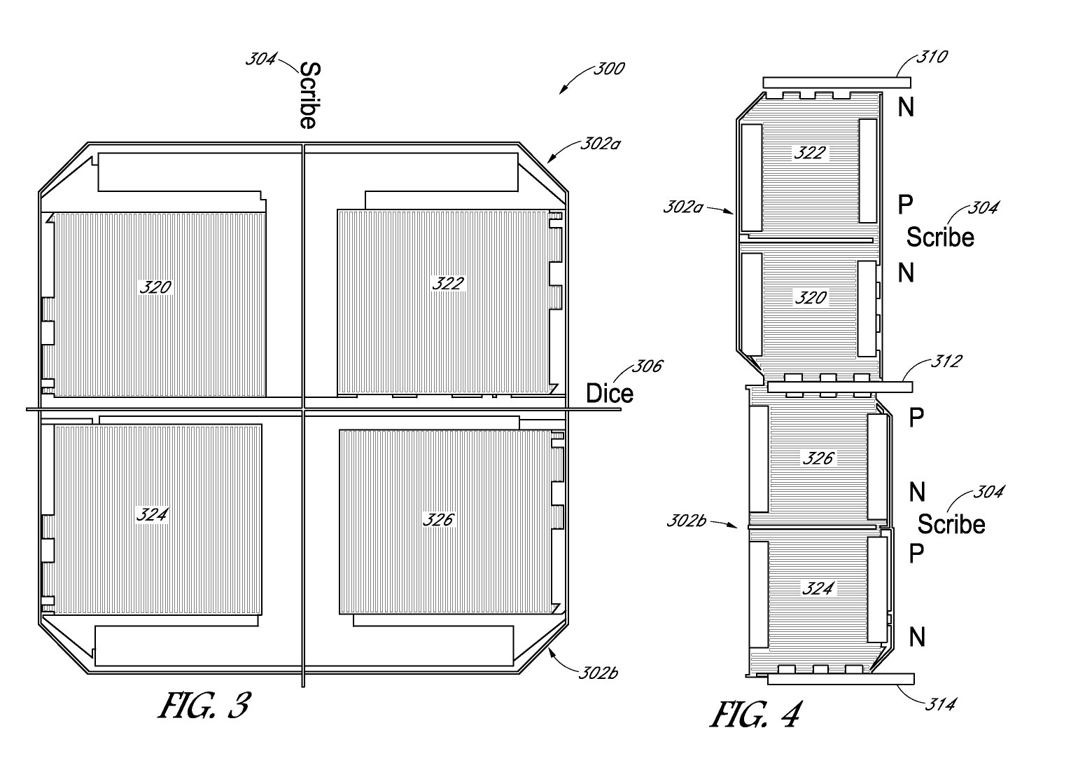

As an exemplary representation of the scribing concepts described herein, FIGS. 1 and 2 illustrate cross-sectional views of a solar cell prior to and subsequent to, respectively, singulation to form physically separated sub-cells, in accordance with an embodiment of the present disclosure.

Referring to FIG. 1, solar cell 100 can include substrate 102 having metallization structure 104 disposed thereon. Solar cell 100 can include alternating N-type and P-type regions in or above substrate 102. In one embodiment, metallization structure 104 is a monolithic metallization structure, as is described in greater detail below. Referring to FIG. 2, solar cell 100 has been singulated or diced to provide solar cell 106 having sub-cells 108 and 110 which are physically separated from one another. In one embodiment, solar cell 100 is singulated using laser ablation, which is described in greater detail below. In an embodiment, as is also depicted in FIG. 2, portion 116 of metallization structure 104 bridges two sub-cells 108 and 110. In a particular embodiment, sub-cells 108 and 110 provide series or parallel diode structures, examples of which are described in detail below.

Referring again to FIGS. 1 and 2, portion 116 of metallization structure 104 is used as both mechanical support and a back-stop during dicing, e.g., during laser ablation of substrate 102 material. In a first particular example, FIG. 2 illustrates a cross-sections view of a portion of a pair of singulated sub-cells using metal as a back-stop for cell singulation, in accordance with an embodiment of the present disclosure. As shown in FIG. 2, sub-cells 108 and 110 are formed upon singulation of substrate 102, having groove 112 there between. Portion 116 of the metallization structure 104 can be formed directly on the back surface of substrate 102 and, as such, a metal or metallic region is used as a back-stop during singulation.

In the example of FIG. 2, it is to be appreciated that, in an embodiment, metallization structure 104 can be viewed as a monolithic metallization structure, as described in greater detail below. Furthermore, in an embodiment, in either case, a sub-cell interconnect is fabricated in a same operation as the sub-cell metal. Alternatively, a sub-cell interconnect may be externally applied, but additional processing operations would be needed.

Referring again to FIGS. 1 and 2, more generally, in an embodiment, a solar cell includes a plurality of sub-cells. Each of the sub-cells can have a singulated and physically separated semiconductor substrate portion. Adjacent ones of the singulated and physically separated semiconductor substrate portions can have a groove there between. The solar cell can also include a metallization structure. A portion of the metallization structure couples ones of the plurality of sub-cells. Furthermore, the groove between adjacent ones of the singulated and physically separated semiconductor substrate portions exposes a portion of the metallization structure.

In an embodiment, the metallization structure is fabricated from a foil (e.g., a conductive foil, such as an aluminum foil with or without an additional seed layer) or is fabricated by a plating process. The metallization structure may be fabricated by plating, printing, by use of a bonding procedure (e.g., in the case of a foil), or may be fabricated by a by a deposition, lithographic, and etch approach. In one such embodiment, in the case that a relatively thick (e.g., greater that approximately 25 microns) back metal is used, some tolerance for partial laser ablation into the metal may be accommodated. However, if a thin metallization structure is used (e.g., less than approximately 25 microns), ablation may need to be halted without any scribing of the metallization structure, so as to maintain the electrical and physical integrity of the metal required to survive reliability testing. Accordingly, in various embodiments, the disclosed techniques can provide a way to halt the scribing while inhibiting damage to the metallization structure.

In an embodiment, the metallization scheme is used to hold and provide mechanical integrity for the sub-cells together within the parent cell, such that additional handling complexity is not necessarily required when building the module, and the cells remain physically separated.

In one embodiment, the emitter is designed so that the scribe falls primarily or entirely within the N-doped region, which has a lower recombination rate when unpassivated than the unpassivated P-doped region, and therefore results in significantly less power loss. In another embodiment, the emitter and scribe are designed so that there is little or no intersection of the scribe with a P—N junction, since unpassivated junctions have significantly higher recombination resulting in more power loss.

In one embodiment, a buffer stop (e.g., a polymer such as polyimide) can be implemented in addition to the scribing depth control techniques, to provide a backup to inhibit damage to the metallization structure. The polymer can be globally deposited and then patterned or may be deposited only in desired, e.g., by printing. In other embodiments, such a buffer stop is composed of a dielectric material such as, but not limited to, silicon dioxide (SiO₂), silicon nitride (SiN) or silicon oxynitride (SiON). In one such embodiment, the dielectric material can be formed using a deposition technique such as, but not limited to, low pressure chemical vapor deposition (LPCVD), plasma enhanced chemical vapor deposition (PECVD), high density plasma chemical vapor deposition (HDPCVD) or physical vapor deposition (PVD).

It is to be appreciated that one or more embodiments described herein involve implementation of metallization that is single-level ‘monolithic’ across all sub-cells. Thus, the resulting cell metallization can be identical to the interconnect metallization and fabricated in the same process, at the same time. In one such embodiment, use of a monolithic metallization structure leads to implementation of cell isolation as completed subsequent all diodes being metallized. This is distinguished from conventional approaches where metallization is a multi-step process. In more particular embodiments, a monolithic metallization approach is implemented in conjunction with a buffer or protective layer over which the monolithic metallization structure is formed. Such embodiments can allow for ablation stop on the buffer or protective layer without exposing the metal itself.

In some embodiments, an encapsulating material, e.g., ethylene vinyl alcohol (EVA), poly-olefin, can be disposed in the groove between adjacent ones of the singulated and physically separated semiconductor substrate portions. In one such embodiment, the encapsulant provides shunt resistance as well as wear resistance between adjacent sub-cell portions.

In accordance with an embodiment of the present disclosure, each sub-cell of a diced solar cell has approximately a same voltage characteristic and approximately a same current characteristic. In an embodiment, the plurality of sub-cells is a plurality of in-parallel diodes, in-series diodes, or a combination thereof. In an embodiment, the solar cell and, hence, the sub-cell portions, is a back-contact solar cell, and the metallization structure is disposed on the back surface, opposite a light-receiving surface, of each of the singulated and physically separated semiconductor substrate portions. In one such embodiment, the back surface of each of the sub-cells has approximately a same surface area. In a particular embodiment, the light-receiving surface of each of the sub-cells is a texturized surface, as is described in greater detail below.

In accordance with an embodiment of the present disclosure, the semiconductor substrate portions can be bulk monocrystalline silicon substrate portions, such as fabricated from an N-type monocrystalline substrate. In one such embodiment, each silicon portion includes one or more N+ regions (e.g., phosphorous or arsenic doped regions) and one or more P+ regions (e.g., boron doped regions) formed in substrate itself. In other embodiments, each silicon portion includes one or more polycrystalline silicon N+ regions and one or more polycrystalline silicon P+ regions formed above a silicon substrate.

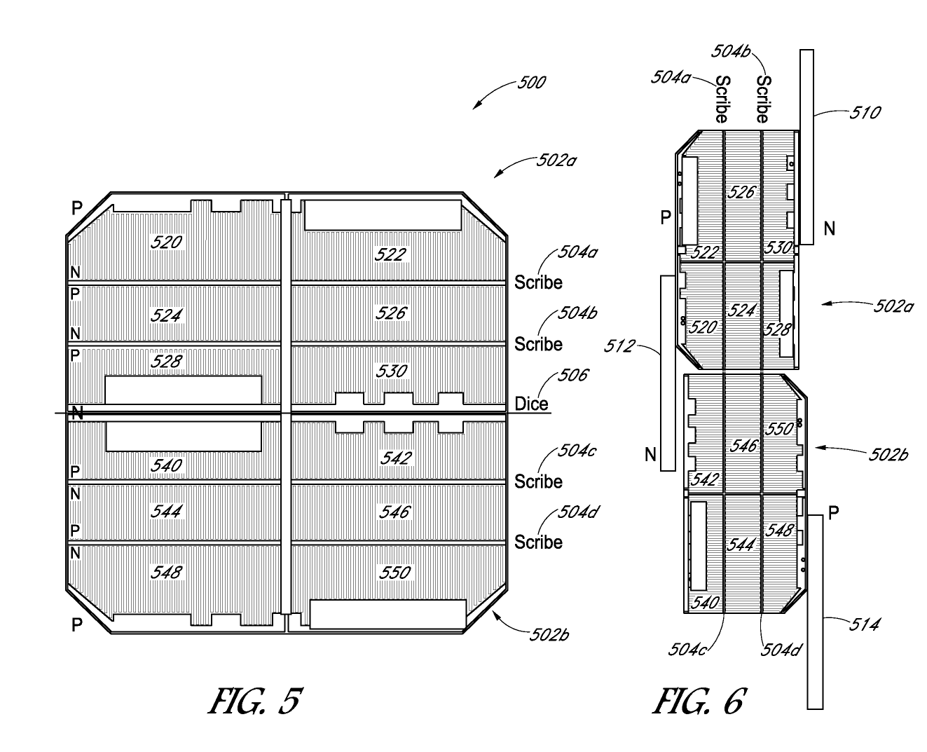

It is to be appreciated that a variety of arrangements of numbers and electrically coupling of sub-cells within a singulated solar cell may be contemplated within the spirit and scope of embodiments described herein. In a first example, FIG. 3 illustrates a plan view from the metallization side of a full wafer solar cell 300 that has been diced at 306 into two half wafers 302a and 302b with the half wafers having been scribed at 304 such that the half wafers each have two sub-cells, in accordance with an embodiment of the present disclosure. As shown, half wafer 302a can be singulated to provide two sub-cells 320 and 322 such that the semiconductor substrate portions of the sub-cells are physically separated from one another with a groove. Similarly, half wafer 302b can be singulated to provide two sub-cells 324 and 326 such that the semiconductor substrate portions of the sub-cells are physically separated from one another with a groove. As described herein and as shown in the numerous examples throughout the specification, in other embodiments, other numbers of sub-cells can exist, for example, four sub-cells, six sub-cells, or some other number of sub-cells per half wafer.

As shown in FIG. 3, a metallization structure, including the illustrated metallization lines (or fingers), is used to hold the two-sub-cell design together for each half wafer where the respective sub-cells meet. In one embodiment, stress-relief features can be included in the metallization lines.

In one embodiment, the scribe cut can be performed on diffusion regions with the lowest recombination post isolation.

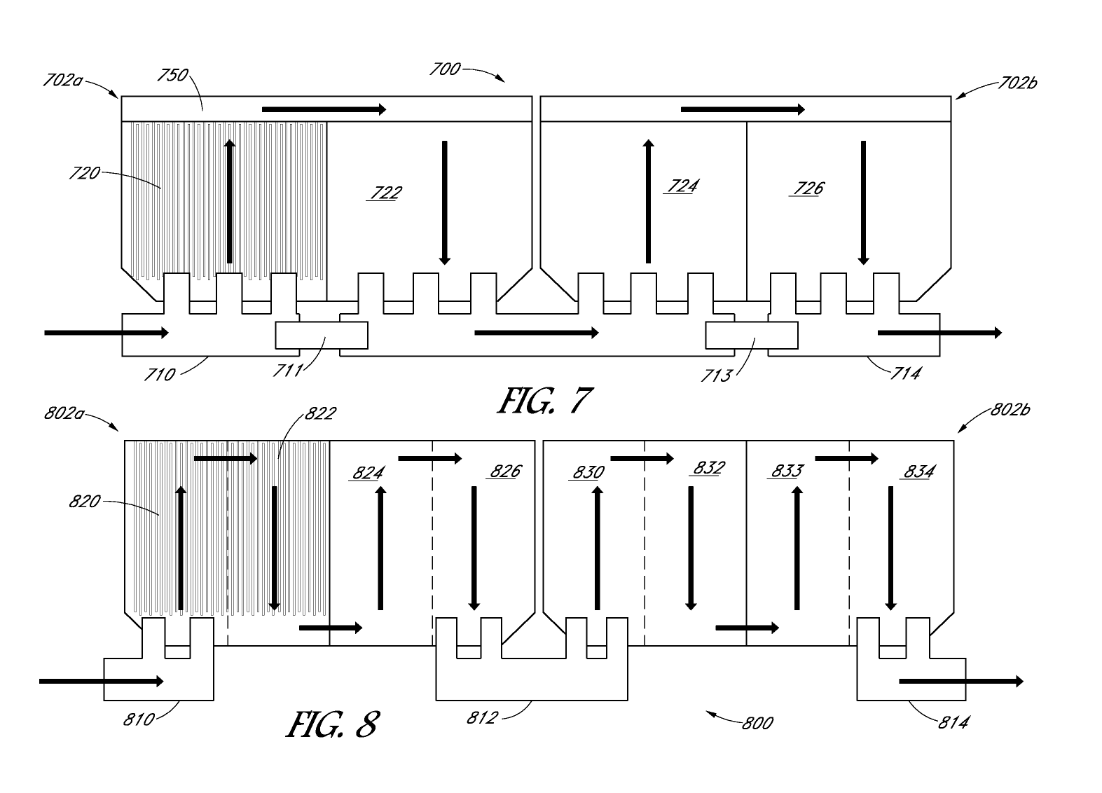

FIG. 4 illustrates the two-diode half-wafer solar cells of FIG. 3 coupled together to form a concentrating photovoltaic receiver. As shown, interconnect structure 312 disposed between half wafers 302a and 302b can couple the respective metallization structures of the half wafers together. Also shown in FIG. 4, interconnect structures 310 and 314 can be used to couple to other half wafers that are not illustrated in FIG. 4 or to couple to a cable or junction box to deliver to a load.

The receivers illustrated and described through, including the receiver of FIG. 4, can be part of a concentrating photovoltaic structure that includes optics (e.g., mirrors, lenses) configured to concentrate light on the receiver during normal operation.

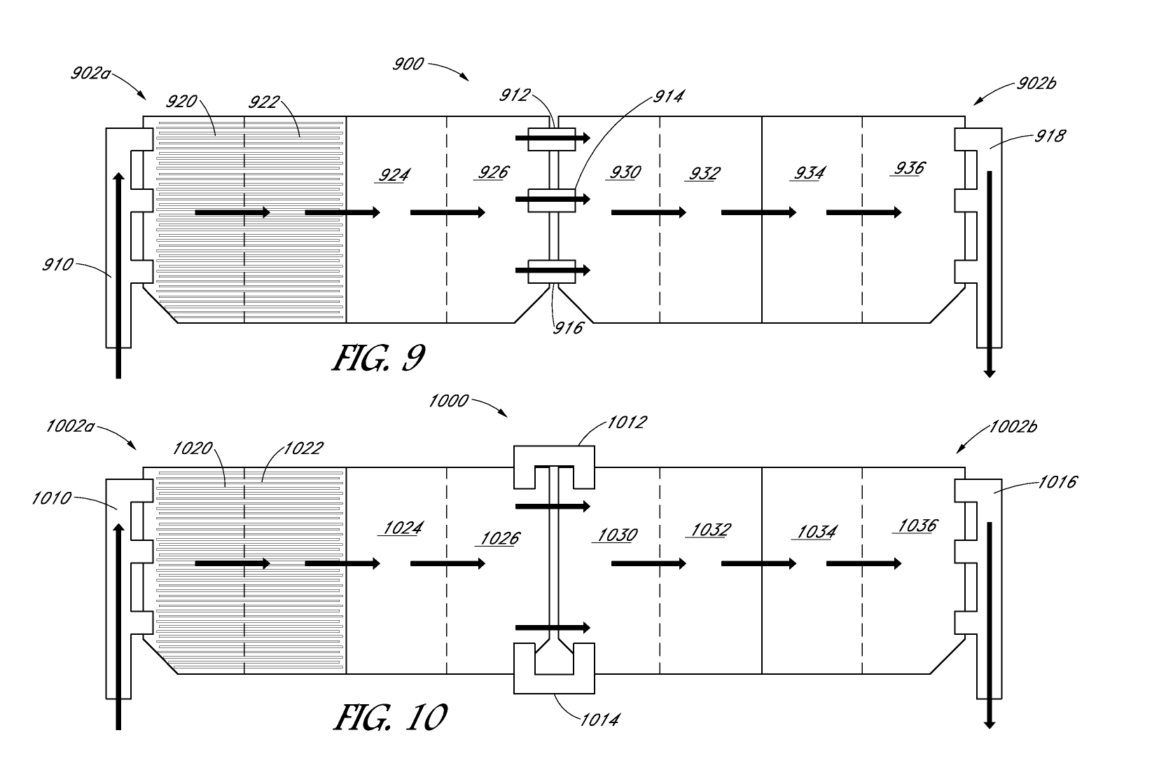

FIG. 5 illustrates another example of a concentrating PV receiver that includes multiple half wafers each having a plurality of sub-cells. As shown, FIG. 5 illustrates a plan view from the metallization side of a full wafer solar cell 500 that has been diced at 506 into two half wafers 502a and 502b with the half wafers having been scribed at 504a, 504b, 504c, 504d, and 504e such that the half wafers each have six sub-cells, in accordance with an embodiment of the present disclosure. As shown, half wafer 502a can be singulated to provide six sub-cells 520, 522, 524, 526, 528, and 530 such that the semiconductor substrate portions of the sub-cells are physically separated from one another with a groove but coupled together with a metallization structure. Similarly, half wafer 502b can be singulated to provide six sub-cells 540, 542, 544, 546, 548, and 550 such that the semiconductor substrate portions of the sub-cells are physically separated from one another with a groove but coupled together with a metallization structure.

As shown in FIG. 5, a metallization structure, including metallization lines, is used to hold the six-sub-cell design together for each half wafer where the respective sub-cells meet. In one embodiment, stress-relief features can be included in the metallization lines.

For each of the illustrated half wafers of FIG. 5, the current is 0.6× and the voltage is 1.8× of the example of FIG. 3. As noted above, for concentrating photovoltaic applications, thicker metal is typically required to accommodate higher current present for such applications. By using the disclosed techniques and structures, such as the embodiment of FIG. 5 and additional embodiments below, increasing the photovoltaic receiver voltage and reducing the current can enable thinner metal. As one example, use of the disclosed techniques and structures with reduced current can enable a metallization structure having a thickness of 30 microns or less to be used in a concentrating PV system.

In one embodiment, the scribe cut can be performed on diffusion regions with the lowest recombination post isolation.

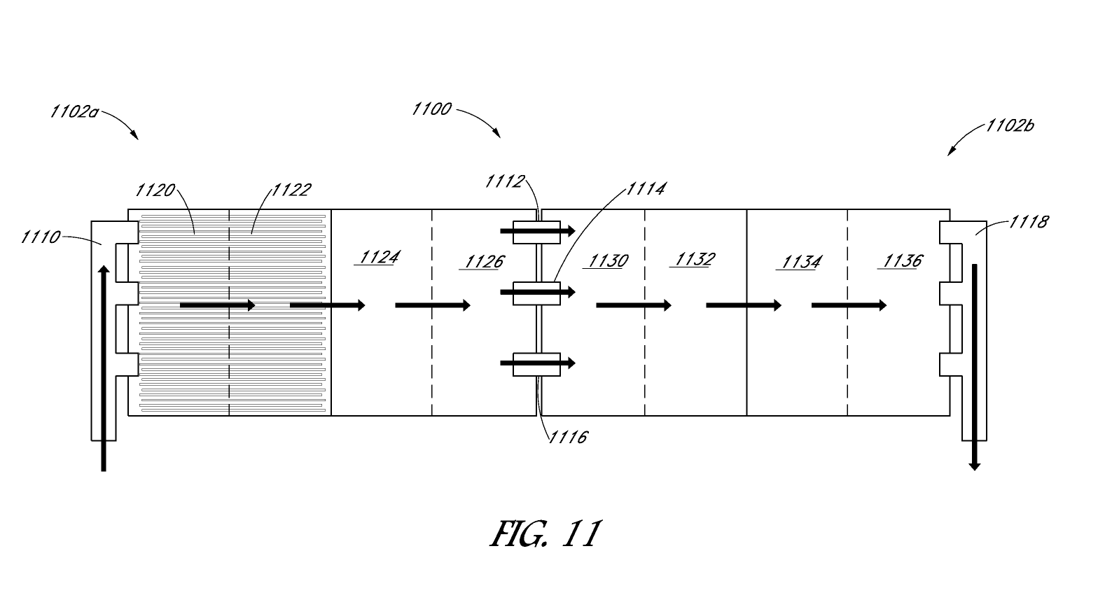

FIG. 6 illustrates the two-diode half-wafer solar cells of FIG. 5 coupled together to form a concentrating photovoltaic receiver. As shown, interconnect structure 512 disposed offset relative to half wafers 502a and 502b can couple the respective metallization structures of the half wafers together. Also shown in FIG. 6, interconnect structures 510 and 514 can be used to couple to other half wafers that are not illustrated in FIG. 6 or to couple to a cable or junction box to deliver to a load. As shown in the example of FIG. 6, the scribes and sub-cells are orientated such that the resulting grooves are substantially perpendicular to the flux beam of the concentrated light received from the optics of a concentrated PV system during operation. Although the sub-cells are illustrated in the example of FIG. 6 as approximately the same size, because the intensity profile of the beam is not necessarily uniform and can vary throughout the day, the sub-cells can be size differently such that approximately the same current is produced by each of the sub-cells.

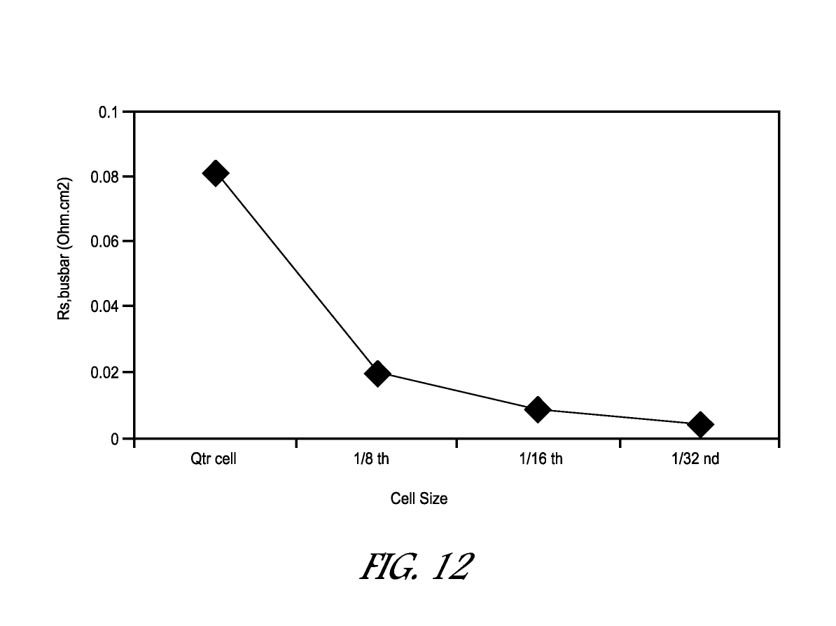

FIGS. 7-11 illustrate other example configurations for concentrating PV receivers according to some embodiments. FIG. 7 illustrates a concentrating PV receiver 700 with a half-wafer form factor as in FIGS. 4 and 6 with a quarter-cell scribe as in FIG. 4. As shown, half wafer 702a includes two sub-cells, 720 and 722 and similarly, half wafer 702b includes two sub-cells 724 and 726. The metallization structures of half wafers 702a and 702b are coupled together with interconnect structure 712. Also shown are interconnect structures 710 and 714, which can be used to couple half wafers 702a and 702b to other half wafers, respectively, or to a load. Also shown are in-laminate bypass diodes 711 and 713 coupled between respective pairs of interconnect structures. Such in-laminate diodes can be used to protect the receiver in the event of a hotspot occurrence. In the illustrated embodiment, the receiver of FIG. 7 can use approximately half the number of interconnects compared to a concentrating PV receiver that does not use the disclosed half wafers with sub-cells.

The arrows of FIG. 7 illustrate the general current flow pattern in which the current the current flow follows a serpentine pattern from one sub-cell to the next and from one half wafer to the next. In such a flow pattern, the fingers of the metallization structures of the sub-cells can be considered to be substantially perpendicular to the flux beam of light during operation. Or, in the example of FIG. 7, such a finger pattern can be referred to as being substantially parallel to the groove(s) or scribe(s).

FIG. 8 illustrates a concentrating PV receiver 800 with a half-wafer form factor as in FIGS. 4, 6, and 7 with an eighth-cell scribe. As shown, half wafer 802a includes four sub-cells, 820, 822, 824, and 826 and similarly, half wafer 802b includes four sub-cells 830, 832, 834, and 836. Such a configuration can result in ½ current and two times the voltage of the approach of FIG. 3 or 7. The metallization structures of half wafers 802a and 802b are coupled together with interconnect structure 812, which is shorter in length than interconnect structure 712 of FIG. 7. Also shown are interconnect structures 810 and 814, which can be used to couple half wafers 802a and 802b to other half wafers, respectively, or to a load. Note also that interconnect structures 810 and 814 are shorter in length than interconnect structures 710 and 714 of FIG. 7. Accordingly, the amount of interconnect material can be reduced by about 50% over the receiver of FIG. 7 or approximately a 75% reduction in the interconnect structures over a system that does not use a half wafer form factor with sub-cells. Notably in FIG. 8, because of the reduced current, the risk of hotspots can be reduced and, as a result, in-laminate bypass diodes may not be needed for receiver 800.

As was the case with FIG. 7, the current flow of concentrating PV receiver 800 of FIG. 8 follows a serpentine pattern from one sub-cell to the next and from one half wafer to the next. Accordingly, the fingers of the metallization structures of the sub-cells of FIG. 8 can be considered to be substantially perpendicular to the flux beam of light during operation and can also be considered to be substantially parallel to the groove(s) or scribe(s).

Turning now to FIG. 9, FIG. 9 illustrates a concentrating PV receiver 900 with a half-wafer form factor and an eighth-cell scribe. As shown, half wafer 902a includes four sub-cells, 920, 922, 924, and 926 and similarly, half wafer 902b includes four sub-cells 930, 932, 934, and 936. Such a configuration can result in ½ current and two times the voltage of the approach of FIG. 3 or 7. In contrast to the PV receiver of FIG. 8, the metallization structure of concentrating PV receiver 900 of FIG. 9 has fingers substantially parallel to the flux beam of light during operation, which can also be considered to be substantially perpendicular to the groove(s) or scribe(s) of receiver 900.

As shown, the metallization structures of half wafers 902a and 902b are coupled together with interconnect structures 912, 914, and 916, which can be offset in the z-direction in contrast to on-board interconnects used in other receivers. Although illustrated as three separate interconnect structures, the interconnect structure between half wafers in such an embodiment can be a single unitary interconnect structure (with one or more portions that physically connect to the half wafer), such as a dogbone-type interconnect or an interconnect structure with multiple distinct interconnect pieces. As shown, interconnect structures 910 and 918 can be used to couple the half wafers of receiver 900 to a load. Note that, in the embodiments illustrated and described herein, a concentrating PV receiver can include more than two half wafers. Accordingly, the interior interconnects connecting two half wafers can be repeated until reaching the end half wafer of the receiver at which point an end interconnect, such as interconnects 910 and 918 can be used. Moreover, in various embodiments, depending on the voltage, current, and power configuration based on the number of sub-cells per half wafer, different receiver lengths may be appropriate for different configurations.

As was the case with the receiver of FIG. 8, because of the reduced current, the risk of hotspots can be reduced and, as a result, in-laminate bypass diodes may not be used in receiver 900.

Referring now to FIG. 10, FIG. 10 illustrates a concentrating PV receiver 1000 with a half-wafer form factor and an eighth-cell scribe. As shown, receiver 1000 is the same as receiver 900, except where noted. Accordingly, the description of receiver 900 applies equally to the description of receiver 1000, except as noted with the interior interconnects. In the illustrated embodiment, interior interconnects 1012 and 1014 are disposed offset and over half wafers 1002a and 1002b, in contrast to the interior interconnects 912, 914, and 916 of receiver 900 that are disposed over and between (e.g., overlapping the gap) half wafers.

FIG. 11 illustrates another example concentrating PV receiver with fingers approximately parallel to the flux beam during operation and approximately parallel to the scribes/gaps. As shown, receiver 1100 includes wafers 1102a and 1102b. In one embodiment, wafers 1102a and 1102b can be tall cells that are approximately 90 mm or longer. As shown, the tall cells can be scribed into four sub-cells, such as sub-cells 1120, 1122, 1124, 1126 for wafer 1102a and sub-cells 1130, 1132, 1134, and 1136 for wafer 1102b, respectively. Similar to the receivers of FIGS. 9 and 10, receiver 1100 can result in current that is more than ½ current but less than full current and two times the voltage of a diced-quarter-cell-based concentrating PV receiver or the arrangement of FIG. 7, which can lead to elimination of in-laminate bypass diodes. Moreover, the configuration of FIG. 11 can permit a small gap between wafers 1102a and 1102b than in the other embodiments. The interconnect arrangement can be similar to that described and illustrated for receiver 900 of FIG. 9 (as shown) or similar to that described and illustrated for receiver 1000.

Moreover, additional benefits of the arrangement of FIG. 11 is that it can enable the use of a larger mirror and can enable higher receiver power, which can reduce manufacturing and installation costs.

Some additional advantages of one or more of the receiver configurations described herein can include a lower I²R, more voltage per receiver (and therefore shorter tracker in embodiments in which the concentrating PV receiver is used in a PV tracker system), and fewer cell gaps.

It is to be appreciated that other arrangements for sub-cells may also be achieved using approaches described herein, such as, but not limited to, 1×4, 1×2, 3×3, 4×4, etc., type arrangements. Also, a combination of series and parallel configurations of sub-cells within an original cell is also accessible. Approaches may be beneficial for both back contact and front contact based cells as well as other semiconductor devices.

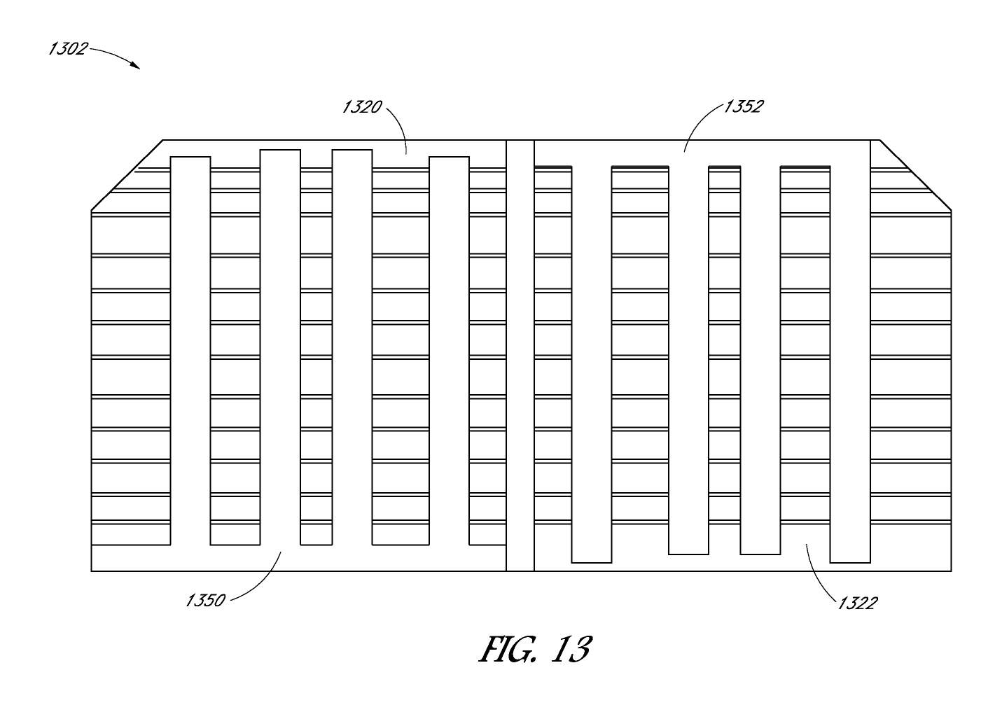

One limitation of a perpendicular-to-the-flux-beam finger pattern, for example, as shown in FIG. 7, is the series resistance (Rs) loss at the busbar (e.g., busbar 750). Example Rs loss in the busbar is illustrated in the graph of FIG. 12. As shown in FIG. 12, by implementing more sub-cells, the busbar series resistance can be reduced exponentially because the width of the busbar can be reduced, thereby allowing more of the cell to be usable rather than be taken up by the busbar. Moreover, in some embodiments, a parallel-to-the-flux-beam finger pattern can result in easier interconnection and can also result in a lower Rs.

For concentrating PV applications, the use of parallel-to-the-flux-beam finger patterns can result in solder pads being located in light receiving regions of the PV receiver, which can result in efficiency loss. In some embodiments, an additional metal layer can be used to enable longer fingers to be used thereby inhibiting pad loss.

As one specific example of an additional metal layer embodiment, a dielectric region (e.g., polyimide) 1401 can be formed on one polarity (e.g., positive) of fingers 1411 and 1413 of the metallization structure at one end of the cell, as shown in the top representation of FIG. 14. On the opposite side of the cell, another dielectric region 1403 can be formed on the other polarity (e.g., negative) fingers 1405 and 1407 of the metallization structure. In one embodiment, the dielectric can be printed and cured in a particular pattern to only apply it to one polarity of fingers. After the dielectric regions are formed at the end of the metallization structure, another metal layer (e.g., 1450 and 1452 on the left representation of FIG. 14 or 1454 and 1456 in the right representation) can be formed (e.g., plated, printed, welded, compressed) on the exposed fingers not covered by the dielectric and on the dielectric (which is not seen in the left or right representation as it is covered by the additional metal layer). The additional metal layer can serve as a pad to which an interconnect structure can be coupled. As described below, in some embodiments, the additional layer technique can be applied before scribing of the silicon takes place.

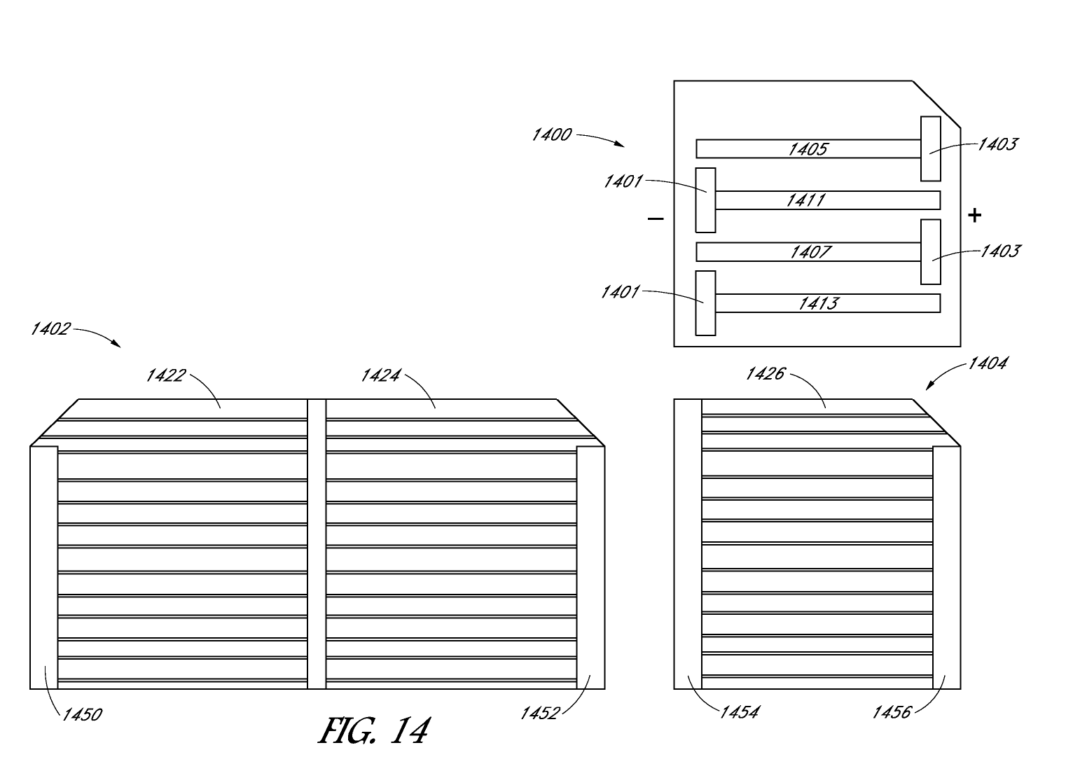

FIG. 13 illustrates an alternative double plating in which the additional metal layer (e.g., 1350 and 1352) is orthogonal to the fingers (e.g., 1320 and 1322) of the metallization structure. Similar to FIG. 14, one or more dielectric regions can be formed such that one polarity of the metallization structure can be insulated from the additional metal layer of the other polarity and vice versa.

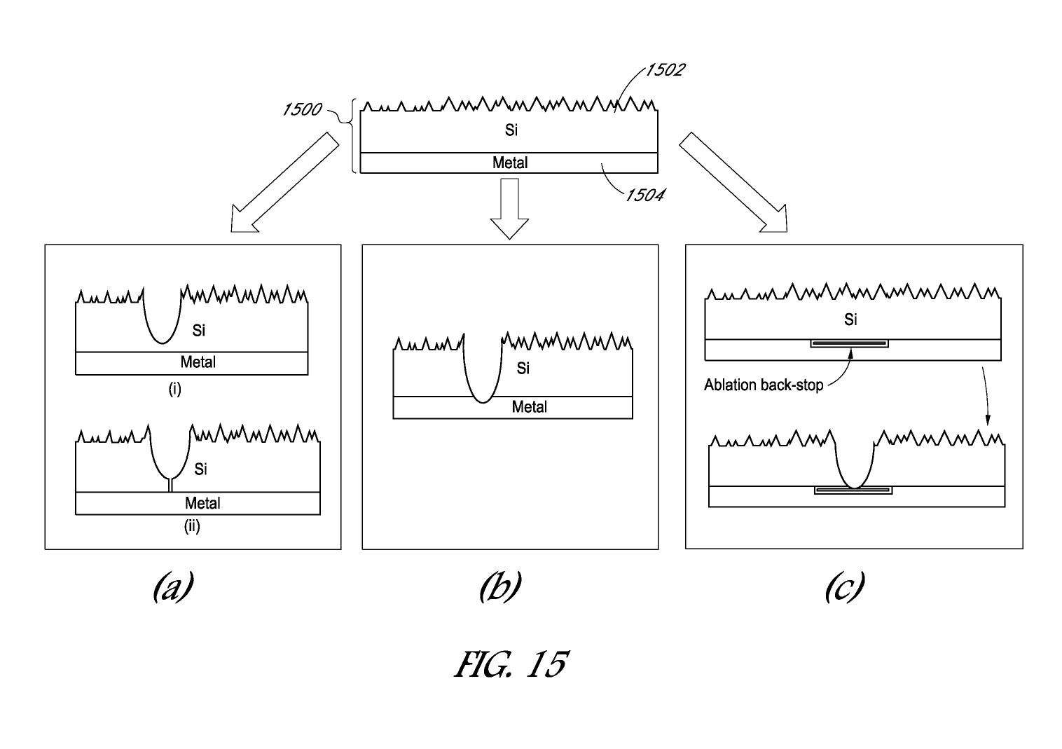

FIG. 15 illustrates three possible pathways for laser scribing for singulation of a solar cell to form sub-cells, in accordance with an embodiment of the present disclosure. Referring to FIG. 15, solar cell 1500 includes a silicon substrate 1502 and a metallization structure 1504 on a back side of the silicon substrate.

Referring to pathway (a) of FIG. 15, a scribe plus break approach is depicted where (i) the substrate is partially scribed (e.g., approximately 70% depth) and then (ii) cracked along the break to terminate at the metallization structure. Referring to pathway (B) of FIG. 15, a scribe-only approach is depicted where the laser ablation of the silicon stops on (or partially into) a metal of the metallization structure. Referring to pathway (a) of FIG. 15, a scribe plus damage buffer break approach is depicted where the laser ablation of the silicon is performed through the entire depth of the silicon and then stops on (or partially into) a damage buffer layer distinct from the metal of the metallization structure. In any of these cases, laser parameter, an option includes pico-second laser ablation having a cleaner process, lower recombination, and narrower scribe width. Another option includes a nano-second or longer laser having wider scribe lines and higher throughput but increased recombination and potential for debris.

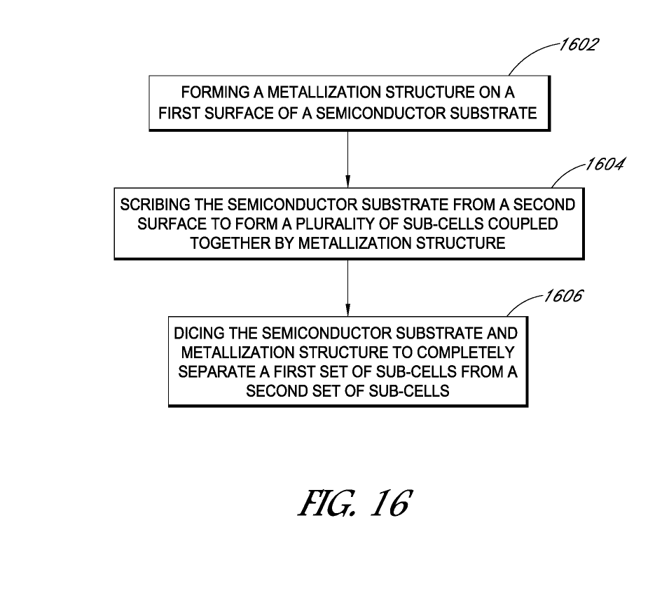

Turning now to FIG. 16, a flow chart illustrating a method for fabricating a concentrating photovoltaic receiver is shown, according to some embodiments. In various embodiments, the method of FIG. 16 may include additional (or fewer) blocks than illustrated. For example, in one embodiment, the method can include forming a dielectric region and an additional metal region on the metallization structure. Or, in another example, the method can include bending the substrate during or after scribing.

As shown at 1602, a metallization structure can be formed on a first surface of a semiconductor substrate. In an embodiment, forming the metallization structure on the first surface of the semiconductor substrate can include forming and patterning (e.g., in a finger pattern, such as a parallel-to-the-flux-beam pattern, perpendicular-to-the-flux-beam pattern, or otherwise) a metal foil. In other embodiments, however, the metallization structure is formed by printing a metal, plating a metal or stack of metals, or by a metal deposition and etch process. In one embodiment, the metallization structure can be formed to have mechanical properties sufficient to bridge at least two sub-cells together through all reliability testing performed in the fabrication and test procedure.

In one embodiment, the metallization structure that is formed at 1602 can be a metallization structure that bridges together multiple sub-cells of a parent solar cell.

As described herein, in some embodiments, a double metal layer can be implemented. For example, in one embodiment, a parallel-to-the-flux-beam finger pattern can be used for the metallization structure and respective dielectric regions can be formed at the ends of the metallization structure with one dielectric region applied to one polarity of the metallization structure and the other dielectric region applied to the other polarity of the metallization structure. An additional metal layer can then be formed (e.g., printed, plated, foil) on the dielectric regions and on the exposed fingers of the polarity not covered by the dielectric regions to effectively form a pad area for interconnection yet enable finger length to the edge of the cell or closer to it.

At 1604, the substrate can be scribed from a second, opposite resulting in exposed portions of the metallization structure from the second surface. Scribing can result in forming a plurality of sub-cells, each of the sub-cells comprising a singulated and physically separated portion of the substrate having a groove between adjacent ones of the singulated and physically separated substrate portions with the metallization structure coupling ones of the sub-cells.

In an embodiment, the scribing is performed with a scribing instrument, such as a laser, of a tooling apparatus. Furthermore, in an embodiment, with the understanding that certain laser parameters may result in side-wall damage, melting, and disruption of the insulating dielectric stack on the rear side, the laser parameters can be selected so as to minimize such damage, melting, and disruption. Typically, this drives a laser selection to shorter pulse-lengths (e.g., less than approximately 10 nanoseconds), and processes that stop short of disrupting the rear dielectric (e.g., groove followed by mechanical separation).

It is to be appreciated that a mechanical scribing process, such as with a saw, milling machine, or etchant may be implemented instead of or in conjunction with a laser scribing process.

In some embodiments, a partial scribe is performed, followed by breaking or sawing the substrate to complete isolation of portions of the substrate. In one embodiment bending the substrate can be performed during scribing, for example, by placing the substrate on a curved (e.g., concave, convex) chuck or surface for the scribing operation. In another embodiment, bending the substrate can be performed after scribing to complete the isolation of the substrate to the metallization structure. Manual breaking can help mitigate the risk of shunting through the base, e.g., by not totally isolating the Si, or having the isolated Si regions touch each other during cycling. In some embodiments, an encapsulant or dielectric can be applied in the gap to further mitigate the shunt risk.

In an embodiment, the method of cell fabrication further involves texturizing the second surface (light-receiving surface) of the semiconductor substrate prior to scribing the semiconductor substrate. Texturizing of the light-receiving surface of the solar cell can, in one embodiment, involve texturizing using a hydroxide-based etch process. It is to be appreciated that a texturized surface may be one which has a regular or an irregular shaped surface for scattering incoming light, decreasing the amount of light reflected off of the light-receiving surface of the solar cell. Accordingly, scribing the substrate at block 1602 can include scribing a textured and non-uniform surface. Note also that other materials (e.g., the metallization structure) may also have variation in thickness.

At 1606, the substrate and the metallization structure can be diced at a particular location to completely separate a first set of sub-cells of the solar cell from a second set of sub-cells. For example, in one embodiment, the location can be along a midpoint of one axis of the solar cell to form two half wafer forms, each with a plurality of sub-cells resulting from the scribing at 1604. In various embodiments, the dicing axis can be perpendicular (e.g., example of FIG. 3) or parallel (e.g., example of FIG. 5) to the scribing axis.

Dicing can be performed in a similar manner as the scribing described at 1604. For example, a laser or mechanical tool can be used to perform the dicing. In one embodiment, dicing at 1606 and scribing at 1604 can be performed with the same tool.

In some embodiments, such as in the example of FIG. 11, dicing at 1606 may not be performed. Instead, the full wafer form factor may be used in such embodiments.

One or more benefits or advantages of embodiments described herein include the reduction of the amount of interconnect material for a PV receiver thereby reducing cost of the device, and the reduction of busbar pad loss and/or gap loss from cell-cell spacing, each of which can result in increased efficiency. In addition, because the disclosed structures and techniques can result in lower current, thinner metal can be used, thermal management demands, which can be significant for concentrating PV, can be reduced, and reverse-bias/hot-spot risk can reduced, which can result in another cost savings in the form of bypass diode elimination.

Overall, although certain materials are described specifically above, some materials may be readily substituted with others with other such embodiments remaining within the spirit and scope of embodiments of the present disclosure. For example, in an embodiment, a different material substrate, such as a group III-V material substrate, can be used instead of a silicon substrate. In another embodiment, a polycrystalline or multi-crystalline silicon substrate is used. Furthermore, it is to be understood that, where N+ and P+ type regions are described specifically, other embodiments contemplated include a switched conductivity type, e.g., P+ and N+ type regions, respectively.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of this disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of this application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

1. A photovoltaic laminate, comprising:
a first half wafer comprising a first plurality of sub-cells, each of the sub-cells of the first plurality of sub-cells comprising a singulated and physically separated semiconductor substrate portion, wherein adjacent ones of the singulated and physically separated semiconductor substrate portions have a groove there between; and
a first metallization structure, wherein a portion of the first metallization structure couples ones of the first plurality of sub-cells, wherein the groove between adjacent ones of the singulated and physically separated semiconductor substrate portions exposes a portion of the first metallization structure.

2. The photovoltaic laminate of claim 1, further comprising:
a second half wafer comprising a second plurality of sub-cells, each of the sub-cells of the second plurality of sub-cells comprising a singulated and physically separated semiconductor substrate portion, wherein adjacent ones of the singulated and physically separated semiconductor substrate portions of the have a groove there between; and
a second metallization structure, wherein a portion of the second metallization structure couples ones of the second plurality of sub-cells, wherein the groove between adjacent ones of the singulated and physically separated semiconductor substrate portions exposes a portion of the second metallization structure.

3. The photovoltaic laminate of claim 2, wherein fingers of the first and second metallization structure are substantially perpendicular to the grooves.

4. The photovoltaic laminate of claim 3, further comprising an interconnect structure disposed between the first and second half wafers and coupled to the first and second metallization structures.

5. The photovoltaic laminate of claim 2, further comprising:
a negative dielectric region disposed on negative fingers of the first metallization structure at a first end of the first metallization structure;
a positive pad region disposed on the negative dielectric region and on positive fingers at the first end of the first metallization structure;
a positive dielectric region disposed on positive fingers of the first metallization structure at a second end of the first metallization structure; and
a negative pad region disposed on the positive dielectric region and on negative fingers at the second end of the first metallization structure.

6. The photovoltaic laminate of claim 2, wherein fingers of the first and second metallization structures are substantially parallel to the grooves, further comprising:
a plurality of interconnect structures coupled to the first and second metallization structures; and
in-laminate diodes coupled between particular pairs of the plurality of interconnect structures.

7. The photovoltaic laminate of claim 1, wherein the first metallization structure has a thickness of 30 microns or less.

8. A concentrated photovoltaic system, comprising:
a plurality of solar cells configured to receive concentrated light, each solar cell comprising:
a plurality of sub-cells, each of the sub-cells comprising a singulated and physically separated semiconductor substrate portion, wherein adjacent ones of the singulated and physically separated semiconductor substrate portions have a groove there between; and
a metallization structure, wherein a portion of the metallization structure couples ones of the plurality of sub-cells, wherein the groove between adjacent ones of the singulated and physically separated semiconductor substrate portions exposes a portion of the metallization structure; and
an interconnect structure coupling metallization structures of adjacent ones of the plurality of solar cells.

9. The photovoltaic system of claim 8, further comprising optics configured to concentrate light on the plurality of solar cells.

10. The photovoltaic system of claim 9, wherein the metallization structures include fingers substantially parallel to a flux beam of concentrated light received from the optics during operation of the photovoltaic system.

11. The photovoltaic system of claim 9, wherein the grooves are substantially perpendicular to a flux beam of concentrated light received from the optics during operation of the photovoltaic system.

12. The photovoltaic system of claim 8, wherein each solar cell has a full wafer form factor.

13. The photovoltaic system of claim 8, further comprising an in-laminate diode coupling the interconnect structure to another interconnect structure.

14. The photovoltaic system of claim 8, wherein the plurality of sub-cells includes at least four sub-cells per solar cell.

15. The photovoltaic system of claim 8, wherein, for a solar cell of the plurality of solar cells, one of the plurality of sub-cells is a different size than another one of the plurality of sub-cells.

16. A method of fabricating a solar cell, the method comprising:
forming a metallization structure on a first surface of a semiconductor substrate;
scribing the semiconductor substrate from a second, opposite, surface of the semiconductor substrate to form a plurality of sub-cells coupled together by the metallization structure, the scribing stopped by and exposing portions of the metallization structure from the second surface; and
dicing the semiconductor substrate and the metallization structure to completely separate a first set of the plurality of sub-cells from a second set of the plurality of sub-cells.

17. The method of claim 16, wherein said forming the metallization structure on the first surface of the semiconductor substrate comprises patterning metal formed on the first surface of the semiconductor substrate resulting in a finger pattern that is substantially perpendicular to a direction of said scribing.

18. The method of claim 16, wherein said dicing is performed substantially perpendicular to a direction of said scribing.

19. The method of claim 16, further comprising coupling a portion of the metallization structure on the first set of sub-cells to a portion of the metallization structure on the second set of sub-cells via an interconnect structure.

20. The method of claim 16, further comprising coupling an in-laminate diode to the interconnect structure and to another interconnect structure.
